(19) United States
(12) Patent Application Publication
(10) Pub. No.: US 2019/0163061 A1
(43) Pub. Date: May 30, 2019

(54) POLYIMIDE PRECURSOR AND LITHOGRAPHY PATTERN FORMED BY THE SAME

(71) Applicant: TAIFLEX SCIENTIFIC CO., LTD., KAOHSIUNG CITY (TW)

(72) Inventors: Chi-Shian CHEN, KAOHSIUNG CITY (TW); Bin-Ling TSAI, KAOHSIUNG CITY (TW); Yu-Pei CHEN, KAOHSIUNG CITY (TW); Chiao-Pei CHEN, KAOHSIUNG CITY (TW); Yu-Fu LIAO, KAOHSIUNG CITY (TW); Shih-Chang LIN, KAOHSIUNG CITY (TW); Chen-Ni CHEN, KAOHSIUNG CITY (TW); Tsung-Tai HUNG, KAOHSIUNG CITY (TW); Chiu-Feng CHEN, KAOHSIUNG CITY (TW)

(21) Appl. No.: 15/908,781

(22) Filed: Feb. 28, 2018

(30) Foreign Application Priority Data
Nov. 24, 2017 (TW) 106141056

(51) Int. Cl. G03F 7/038; G03F 7/00; C08L 79/08

(52) U.S. Cl. CPC G03F 7/0387; H01L 21/28123; C08L 79/085; G03F 7/0002

(57) ABSTRACT

The present invention relates to a polyimide precursor and a lithography pattern formed by the same. The polyimide precursor has a repeating unit having a structure of formula (I):

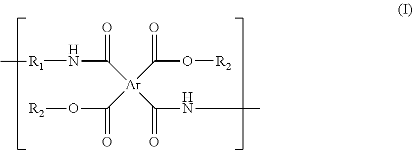

in the formula (I), Ar represents a tetravalent group derivated from a tetracarboxylic dianhydride compound; R₁ represents a divalent group derivated from a diamine compound; and R₂ independently represent a thermal-crosslinking group, a photosensitive-crosslinking group, or a hydrogen atom. The polyimide precursor has an excellent pattern-forming ability.

### RELATED APPLICATIONS

This application claims priority to Taiwan Application Serial Number 106141056, filed on Nov. 24, 2017, which is herein incorporated by reference.

### BACKGROUND

### Field of Invention

The present invention relates to a polyimide precursor and a lithography pattern. More particularly, the present invention provides a polyimide precursor and a lithography pattern with an excellent pattern-forming property.

### Description of Related Art

Dimensions of electrical components are shrunk as lighter and thinner developments of electrical products are provided. In order to simultaneously meet the requirements of dimension-shrinking and signal-transmission, the dimensions of line patterns are gradually shrunk, and a resolution of a linewidth is strictly requested. Therefore, pattern-forming property of the polyimide compound as raw material of a flexible substrate is increasingly important.

In various applications, photosensitive-crosslinking groups are added in polyimide resin to form polyimide precursor and to form lithography pattern by performing coating, exposing, developing and the like.

However, polyamic acid solution formed by the polyimide precursor is easily degraded and hardly stored. Thus, polyimide formed by the polyimide precursor has lower molecular weight, such that the polyimide is easily washed by the development solution, thereby decreasing the resolution of pattern or hardly forming lithography pattern, further lowering operability.

In view of this, there is an urgent need to provide a polyimide precursor and a lithography pattern formed by the same for improving the disadvantages of the conventional polyimide precursor and the lithography pattern formed by the same.

### SUMMARY

Therefore, an aspect of the present invention is to provide a polyimide precursor, and the polyimide precursor has a repeating group having a specific structure, such that the polyimide precursor has an excellent pattern-forming property, thereby performing a lithography process to form a lithography pattern with an excellent resolution.

Another aspect of the present invention is to provide the lithography pattern which is formed by subjecting the aforementioned polyimide precursor to the lithography process.

According to one aspect of the present invention, the polyimide precursor is provided. The polyimide precursor has a repeating unit having a structure of following formula (I):

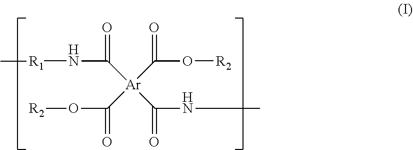

in the formula (I), Ar represents a tetravalent group derivated from a tetracarboxylic dianhydride compound; R₁ represents a divalent group derivated from a diamine compound; and R₂ independently represents a thermal-crosslinking group, a photosensitive-crosslinking group, or a hydrogen atom.

According to one embodiment of the present invention, Ar represents

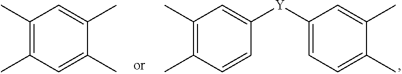

and Y represents a single bond, —O—, —CH₂—, —C(CH₃)₂—, —C(CF₃)₂—, —SO₂—, or —CO—.

According to another embodiment of the present invention, R₁ represents

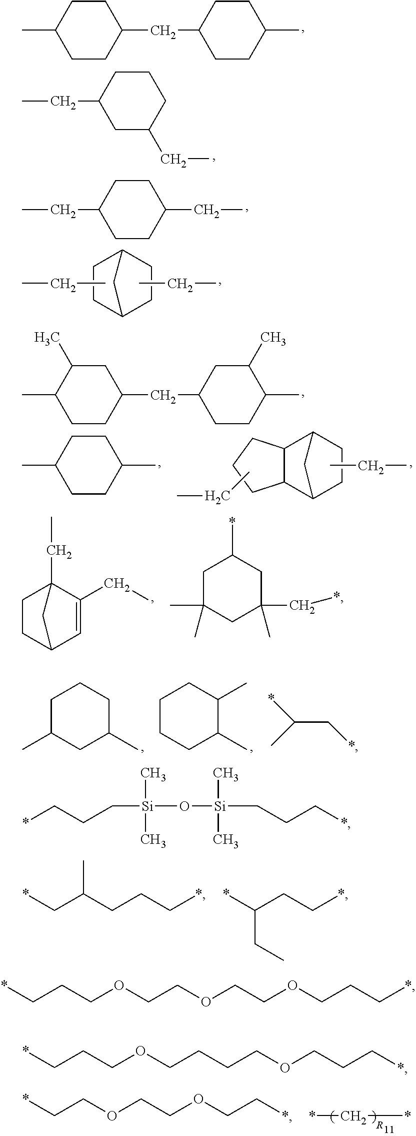

(R₁₁ represents an integer of 3 to 12),

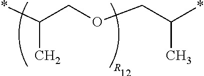

(R₁₂ represents a numeric value of 2 to 68), or

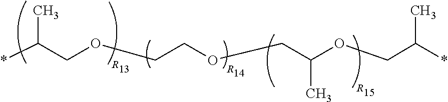

(R₁₄ represents a numeric value of 9 to 39, and a sum of R₁₃ and R₁₅ is a numeric value of 3 to 6).

According to yet embodiment of the present invention, R₂ independently represents

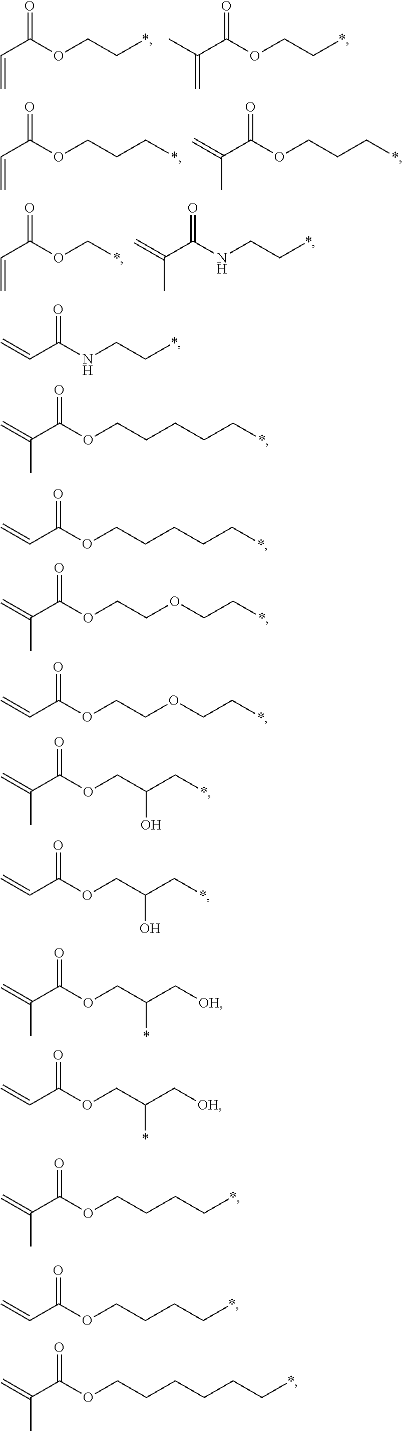

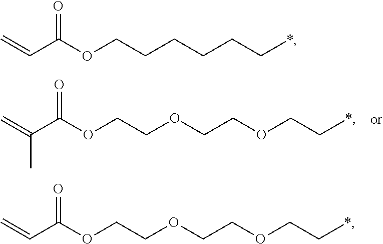

and “*” represents a position where R₂ is bonded with the oxygen atom of formula (I).

According to yet another embodiment of the present invention, a number of the repeating unit of the polyimide precursor is 2 to 150.

According to yet another embodiment of the present invention, two terminals of a molecular chain of the polyimide precursor include a first end-capping group and a second end-capping group. The first end-capping group is bonded with R₁ of the formula (I), and the second end-capping group is bonded with nitrogen atom of the formula (I).

According to yet another embodiment of the present invention, the aforementioned first end-capping group and the second end-capping group respectively is a thermal-crosslinking group.

According to yet another embodiment of the present invention, the first end-capping group has a structure of —X; the second end-capping group has a structure of —R₁—X; X respectively represents

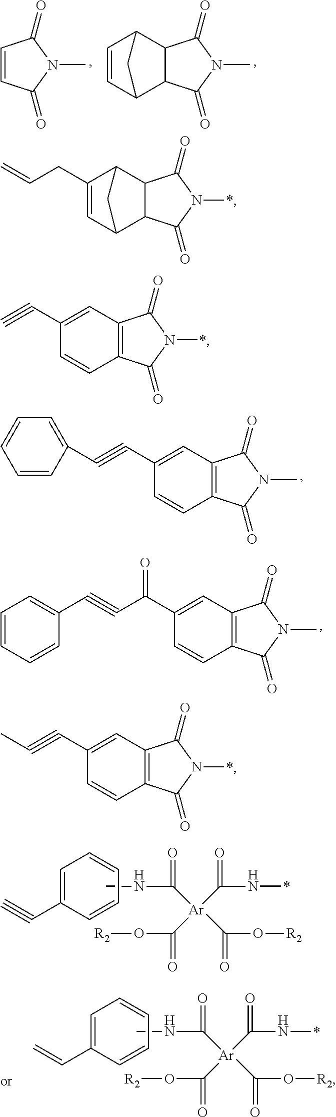

Ar represents a tetravalent group derivated from a tetracarboxylic dianhydride compound, R₂ independently represents the thermal-crosslinking group, the photosensitive-crosslinking group, or the hydrogen atom, and “*” represents a bonding position.

According to yet another embodiment of the present invention, Ar represents

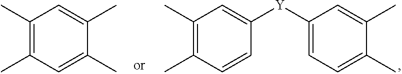

and Y represents a single bond, —O—, —CH₂—, —C(CH₃)₂—, —C(CF₃)₂—, —SO₂—, or —CO—; R₂ represents

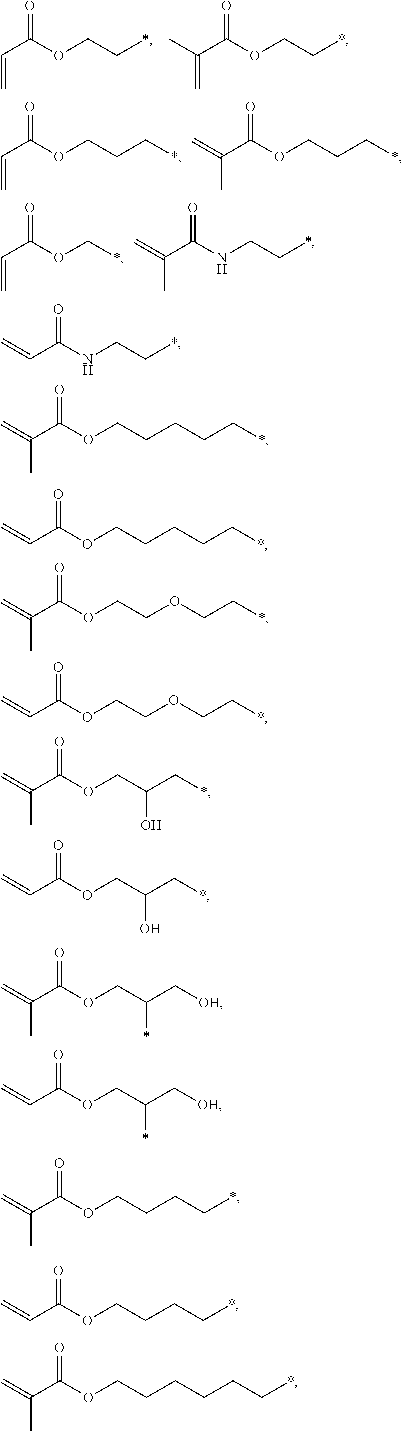

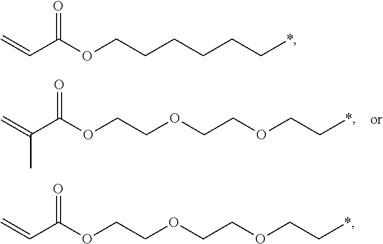

and “*” represents a position where R₂ is bonded with the oxygen atom.

According to another aspect of the present invention, the lithography pattern is provided, and the lithography pattern is formed by subjecting the aforementioned polyimide precursor to the lithography process.

In the polyimide precursor and the lithography pattern formed by the same, the repeating unit of the polyimide precursor is modified by introducing an ester group to reduce activation energy and a cyclization temperature of an imidization reaction, thereby reducing a solubility of the imidizated polyimide precursor in a development solution. Moreover, by introducing the thermal-crosslinking group, the photosensitive-crosslinking group or the hydrogen atom into the repeating unit of the polyimide precursor and energy applied by the lithography process, the solubility of formed polyimide in the development solution can be further reduced, thereby enhancing the pattern-forming property of the polyimide precursor.

### BRIEF DESCRIPTION OF THE DRAWINGS

The invention can be more fully understood by reading the following detailed description of the embodiment, with reference made to the accompanying drawings as follows:

FIG. 1A shows an optical microscope photograph of a lithography pattern formed according to Applied Example 1 of the present invention.

FIG. 1B shows another optical microscope photograph of a lithography pattern formed according to Applied Example 1 of the present invention.

FIG. 1C shows an enlarged photograph of the lithography pattern with a linewidth of 8 μm, 9 μm, 10 μm and 15 μm of FIG. 1A.

FIG. 1D shows an enlarged photograph of a dot pattern with a width of 20 μm of FIG. 1B.

FIG. 2A shows an optical microscope photograph of a lithography pattern formed according to Applied Example 2 of the present invention.

FIG. 2B shows a photograph of a substrate of Applied Example 2 after the lithography process is performed.

FIG. 3 shows a photograph of a substrate of Comparative Applied Example 1 after the lithography process is performed.

### DETAILED DESCRIPTION

In the following description, several specific details are presented to provide a thorough understanding of the device structures according to embodiments of the present invention. One skilled in the relevant art will recognize, however, that the embodiments of the present invention provide many applicable inventive concepts which can be practiced in various specific contents. The specific embodiments discussed hereinafter are used for explaining but not limited of the scope of the present invention.

The present invention provides a polyimide precursor. The polyimide precursor has a repeating unit having a structure of following formula (I):

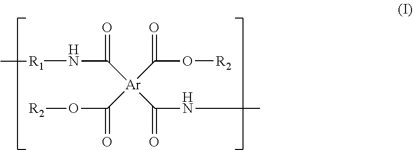

in the formula (I), Ar represents a tetravalent group derivated from a tetracarboxylic dianhydride compound; R₁ represents a divalent group derivated from a diamine compound; and R₂ independently represents a thermal-crosslinking group, a photosensitive-crosslinking group, or a hydrogen atom.

The aforementioned tetravalent group represented by Ar can include

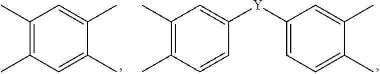

or other suitable tetravalent groups derivated from tetracarboxylic dianhydride compounds. Y can represent a single bond, —O—, —CH₂—, —C(CH₃)₂—, —C(CF₃)₂—, —SO₂—, —CO—, or a combination thereof.

R₁ can be a divalent group derivated from a diamine compound having aliphatic groups, and the divalent group (in the following divalent group, “*” represents a bonding position) can include

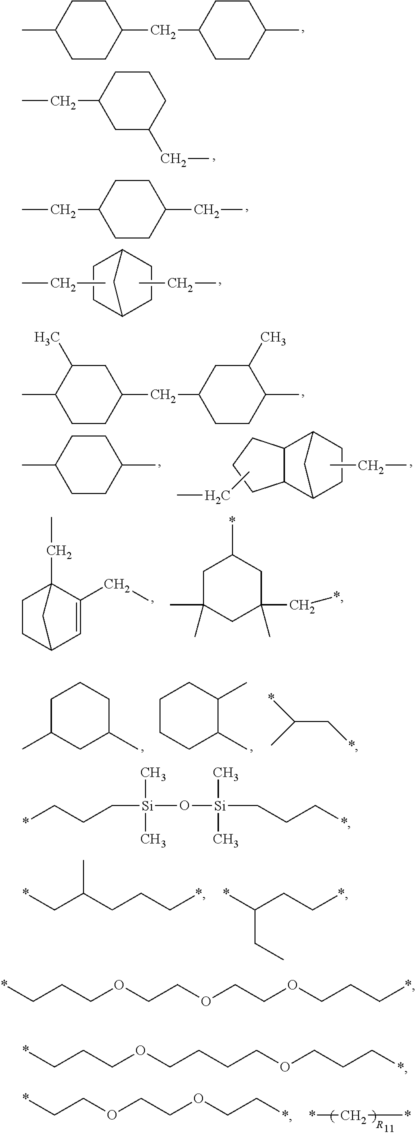

(R₁₁ represents an integer of 3 to 12),

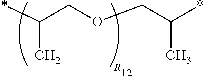

(R₁₂ represents a numeric value of 2 to 68),

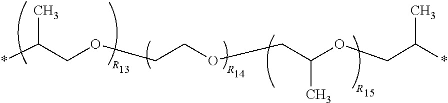

(R₁₄ represents a numeric value of 9 to 39, and a sum of R₁₃ and R₁₅ is a numeric value of 3 to 6), or other suitable divalent group derivated from the diamine compound having the aliphatic groups. In some embodiments, a number of carbons of the divalent group preferably can be 6 to 18, and more preferably can be 8 to 16.

In one embodiment, the thermal-crosslinking group or photosensitive-crosslinking group represented by R₂ can include but be not limited to

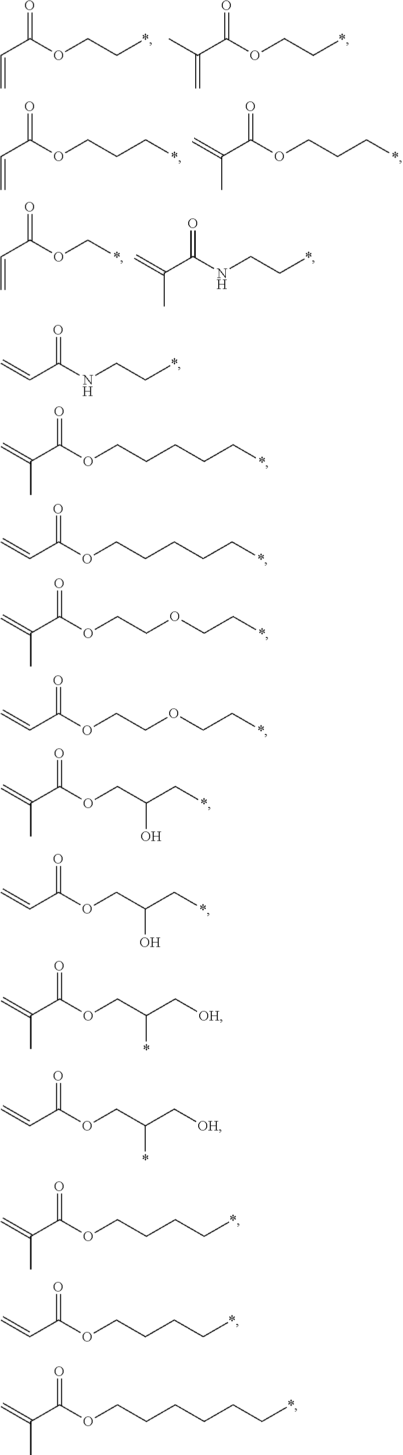

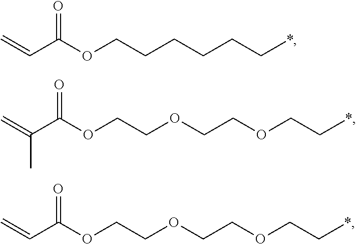

or other suitable thermal-crosslinking group or photosensitive-crosslinking group. In the aforementioned structures represented by R₂, “*” represents a position where R₂ is bonded with the oxygen atom of formula (I). In some embodiments, a number of carbons of the thermal-crosslinking group or photosensitive-crosslinking group represented by R₂ preferably can be 3 to 10. In some embodiments, a plurality of R₂ in the formula (I) respectively can be the same as each other or be different groups.

In some embodiments, the polyimide precursor of the present invention can be random copolymer, block copolymer, alternative copolymer, other suitable copolymers, or a combination thereof. In other words, each of the repeating units in the polyimide precursor can be the same as each other of be different. In some embodiments, a number of the repeating unit of the polyimide precursor is 2 to 150. The number of the repeating unit of the polyimide precursor preferably can be 5 to 120, and more preferably can be 10 to 100. When the number of the repeating unit of the polyimide precursor is 2 to 150, the polyimide precursor has an excellent pattern-forming property.

In some embodiments, two terminals of a molecular chain of the polyimide precursor of the present invention have a first end-capping group and a second end-capping group, and the first end-capping group and the second end-capping group respectively are thermal-crosslinking groups. The first end-capping group and the second end-capping group can be same thermal-crosslinking group or different thermal-crosslinking groups. In some embodiments, the first end-capping group is bonded with the terminal R₁ of the repeating unit shown as the formula (I), and the second end-capping group is bonded with the terminal nitrogen atom of the repeating unit shown as the formula (I). When the terminals of the molecule chain of the polyimide precursor includes the first end-capping group and the second end-capping group, a molecular weight of the polyimide precursor can be suitably controlled. Moreover, the thermal-crosslinking groups can be bonded with another thermal-crosslinking group, thereby elongating molecular sections of the polyimide, further providing much better pattern-forming property.

In some embodiments, the first end-capping group can have a structure of —X, and the second end-capping group can have a structure of —R₁—X. The first end-capping group (i.e. —X) is bonded with the terminal R₁ of the repeating unit shown as the formula (I), and the second end-capping group (i.e. —R₁—X) is bonded with the terminal nitrogen atom of the repeating unit shown as the formula (I). In those embodiments, X respectively represents

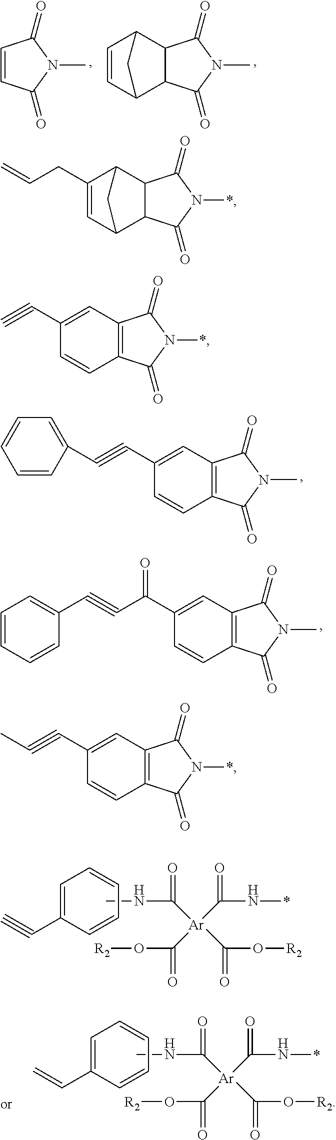

The definition of Ar and R₂ is the same as above, and “*” represents a bonding position.

In some embodiments, the polyimide precursor of the present invention can have a structure shown as following formula (II):

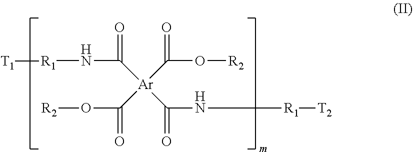

in the formula (II), the definitions of Ar, R₁ and R₂ are the same as above rather than focusing or mentioning them in details; T₁ and T₂ respectively represents the thermal-crosslinking group; and m represents an integer of 2 to 150. Between the repeating units, Ar, R₁, and R₂ in different repeating units can be the same or different. In each of the repeating units, a plurality of R₂ in the repeating unit can be the same or different.

In some embodiments, T₁ and T₂ respectively can represent

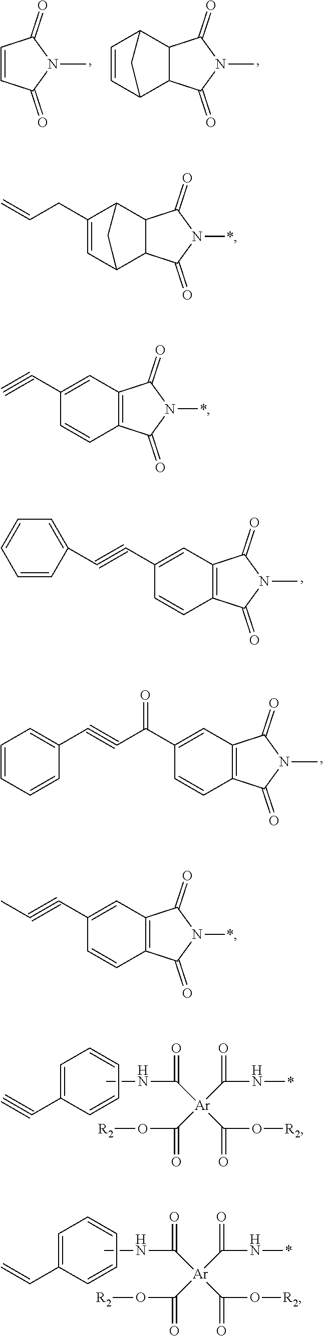

or other suitable thermal-crosslinking groups. The definitions of Ar and R₂ are the same as above, and “*” represents a bonding position.

In one example of the polyimide precursor of the present invention, a tetracarboxylic dianhydride compound having aromatic groups and a diamine compound are firstly subjected to copolymerization reaction to form polyamic acid. Then, the polyamic acid and an alcohol compound having R₂ group are subjected to an esterification reaction, thereby forming the polyimide precursor having the repeating unit shown as the aforementioned formula (I).

In another example of the polyimide precursor of the present invention, a tetracarboxylic dianhydride compound having aromatic groups and a diamine compound are firstly subjected to copolymerization reaction to form polyamic acid. Then, the polyamic acid is subjected to an end-capping reaction, so as to control molecular weight of the polyimide precursor to a suitable range. And then, the polyamic acid having the end-capping groups and an alcohol compounds having R₂ group are further subjected to an esterification reaction, thereby forming the polyimide precursor shown as the aforementioned formula (II).

In yet another example of the polyimide precursor of the present invention, a tetracarboxylic dianhydride compound having aromatic groups and a diamine compound are firstly subjected to copolymerization reaction to form polyamic acid. Next, the polyamic acid is subjected to an end-capping reaction, so as to control molecular weight of the polyimide precursor to a suitable range. Then, the polyamic acid having end-capping groups is subjected to a reaction, so as to form polyisoimide (PII). And then, polyisoimide and an alcohol compounds having R₂ group are further subjected to an esterification reaction, thereby forming the polyimide precursor shown as the aforementioned formula (II).

The aforementioned tetracarboxylic dianhydride compounds can have a structure shown as following formula (III-1):

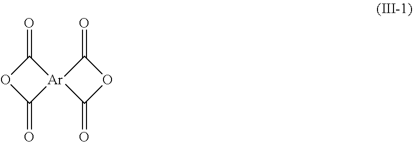

in the formula (III-1), the definitions of Ar and Y are the same as above rather than focusing or mentioning them in details.

For example, the tetracarboxylic dianhydride compounds can include but be not limited to 1,2,4,5-benzene tetracarboxylic anhydride (PMDA), 3,3′,4,4′-biphenyl tetracarboxylic dianhydride (BPDA), bis-(3-phthalyl anhydride)ether (ODPA), 3,3′,4,4′-benzophenone tetracarboxylic dianhydride (BTDA), other suitable tetracarboxylic dianhydride compounds or a combination thereof.

In some embodiments, Ar in the formula (III-1) preferably can be

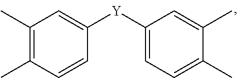

and Y preferably can be —CO—, —O— or the like.

The aforementioned diamine compounds can be compounds derivated from diamine compounds having aliphatic groups. The diamine compounds having aliphatic groups can have a structure shown as following formula (III-2):

H₂N—R₁—NH₂ (III-2)

in the formula (III-2), the definition of R₁ is the same as above rather than focusing or mentioning them in details.

For example, the diamine compounds having aliphatic groups can include but be not limited to 4,4′-diamino dicyclohexyl methane (MBCHA), 1,3-di(aminomethyl)cyclohexane, 1,4-di(aminomethyl)cyclohexane, bis(amino methyl)bicyclo[2.2.1]heptane, 4,4′-methylenebis(2-methylcyclohexylamine), other suitable diamine compounds or a combination thereof. In one example, the diamine compounds having aliphatic groups can include but be not limited to commercial products manufactured by Huntsman Corp., and the trade mark can be Jeffamine D-230, Jeffamine D-400, Jeffamine D-2000, Jeffamine D-2010, Jeffamine D-4000, Jeffamine ED-600, Jeffamine ED-900, Jeffamine ED-2003, XTJ-578 diamine or XTJ-582 diamine; commercial products manufactured by BASF Corp., and the trade mark can be Versamine-551 or Versamine-552; commercial products manufactured by CRODA Inc., and the trade mark can be Priamine™ 1074.

In one embodiment, preferably can be

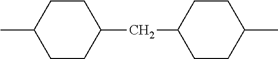

or the like.

In some embodiments, based on an amount of the tetracarboxylic dianhydride compound as 100 mole %, an amount of the diamine compound can be 101 mole % to 120 mole %, preferably can be 102 mole % to 110 mole %, and more preferably can be 104 mole % to 106 mole %.

If the amount of the diamine compound is less than 101 mole %, terminals of the polyamic acid cannot further react with end-capping groups, such that the polyamic acid cannot be reacted to form the polyimide precursor of the present invention.

If the amount of the diamine compound is more than 120 mole %, excess diamine compound merely increases costs of the reaction, and excess diamine compound is not beneficial for effects of the polyimide precursor.

In at least one embodiment, the aforementioned alcohol compounds having R₂ group can have a structure of R₂—OH. After the alcohol compounds having R₂ group and the polyamic acid (or the polyisoimide) are subjected to the esterification reaction, the polyamic acid (or the polyisoimide) can have an ester group, thereby enhancing storage stability and operability.

In some embodiments, R₂ preferably can be

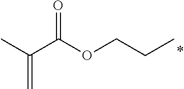

or the like.

Based on an amount of the tetracarboxylic dianhydride compounds as 100 mole %, an amount of the alcohol compounds having R₂ group can be 10 mole % to 300 mole %, preferably can be 50 mole % to 280 mole %, and more preferably can be 100 mole % to 250 mole %.

If the amount of the alcohol compound having R₂ group is less than 10 mole %, the polyimide precursor has less ester groups, thereby increasing the solubility, therefore lowering the pattern-forming property.

If the amount of the alcohol compound having R₂ group is more than 300 mole %, although excess alcohol compound can ensure that the polyimide precursor has sufficient ester groups, excess alcohol compound merely increases costs of the reaction, and excess alcohol compound is not beneficial for the following imidization reaction.

Moreover, based on the amount of the tetracarboxylic dianhydride compound as 100 mole %, an amount of the compound having the aforementioned end-capping groups can be 2 mole % to 50 mole %, preferably can be 4 mole % to 40 mole %, and more preferably can be 8 mole % to 20 mole %.

If the amount of the compound having the aforementioned end-capping groups is less than 2 mole %, all of the two terminals of the molecule chain of the polyimide precursor cannot be completely end-capped by the deficient end-capping groups, such that non-end-capping terminal of one polyimide precursor cannot be bonded with the thermal-crosslinking group (i.e. another end-capping group) of another polyimide precursor during the imidization reaction, therefore keeping the polyimide precursor from being elongated.

If the amount of the compound having the aforementioned end-capping groups is more than 50 mole %, excess end-capping group merely increases costs of the reaction, and excess end-capping group is not beneficial for effects of the polyimide precursor.

Based on different reaction mechanisms and/or different applied requirements, a polymerization initiator can further added into the aforementioned imidization reaction to induce the polyimide precursor to react, thereby forming polyimide polymeric material.

The aforementioned polymerization initiator can include not be not limited to 1-[4-(Phenylthio)phenyl]-1,2-octanedione 2-(O-benzoyloxime), 1-[9-Ethyl-6-(2-methyl benzoyl)-9H-carbazol-3-yl]ethanone 1-(O-acetyloxime), other suitable polymerization initiator or a combination thereof.

Based on the amount of the tetracarboxylic dianhydride compounds as 100 wt %, an amount of the polymerization initiator can be 0.1 wt % to 30 wt %, preferably can be 1 wt % to 20 wt %, and more preferably can be 2 wt % to 15 wt %.

In one example, the polyimide precursor of the present invention can be subjected to the lithography process to form the lithography pattern. In the example, the polyimide precursor of the present invention is firstly dissolved in a solvent to form a solution, and sufficient photo-initiator and crosslinking agent are added into the solution, so as to form polyimide precursory solution. In some embodiments, the solvent can include but be not limited to N-methyl-2-pyrrolidone (NMP), dimethyl acetamide (DMAc), dimethyl sulfoxide (DMSO), dimethyl formamide (DMF), hexamethylphosphoric triamide (HMPA), m-cresol, other suitable solvents, or a combination thereof.

Then, the aforementioned polyimide precursory solution is further coated on a substrate (e.g. a flexible copper foil substrate, a wafer or the like), so as to form a coating film. And then, the substrate coated with the coating film is subjected to the lithography process, thereby forming the lithography of the present invention. In the lithography process of the present invention, the coating film is transferred into the lithography pattern by difference of the solubility of the coating film in the development solution.

When a post-baking step of the lithography process is performed, applied heat can induce one end-capping group (i.e. the thermal-crosslinking group; T₁ and T₂) of one molecule chain in the polyimide precursor to be bonded with another end-capping group of another molecule chain in the polyimide precursor, thereby forming a bonding between the two molecule chains, further elongating the molecular sections. Accordingly, in the polyimide formed from the polyimide precursor with the elongated molecular sections, the thermal-crosslinking groups are bonded with each other to form a stable bonding after the molecule chains are crosslinked and elongated at high temperature, thereby steadying the molecular weight and property of the imidizated polyimide.

In other words, when the molecular sections of the polyimide precursors are not elongated (i.e. the molecular sections are not sufficient long, or the molecular weight is not sufficient high), the solubility thereof is higher in the development solution. Thus, polyimide formed by the polyimide precursors will be developed (i.e. dissolved) by the development solution. Therefore, after the lithography process is performed, the coating film on the substrate will transfer into the lithography pattern.

Several embodiments are described below to illustrate the application of the present invention. However, these embodiments are not used for limiting the present invention. For those skilled in the art of the present invention, various variations and modifications can be made without departing from the spirit and scope of the present invention.

### Producing Polyimide Precursor

### Example 1

At room temperature, 14.94 g (0.071 mole) of 4,4′-diamino dicyclohexyl methane and 150 g (1.513 mole) of N-methyl-2-pyrrolidone (hereinafter abbreviated as NMP) are added into a reaction bottle with water bath. After the reactor is completely dissolved in NMP, 20.78 g (0.067 mole) of bis-(3-phthalyl anhydride)ether is added into the NMP solution, so as to being subjected to react.

After 16 hours, 0.69 g (0.008 mole) of maleic anhydride is added to be subjected to the end-capping reaction. Then, 27.65 g (0.134 mole) of N,N′-dicyclohexylcarbodiimide is added. After the solution is stirred for 1 hour, 17.44 g (0.134 mole) of 2-hydroxyethyl methacrylate is added, thereby performing the esterification reaction to an acidic group of the polyamic acid compound. After byproduct solid of dicyclohexylurea is filtered, polyimide precursor solution mixture is obtained. After water is added into the polyimide precursor solution mixture, precipitate is filtered and dried, thereby obtaining the polyimide precursor of Example 1. A molecular weight of the polyimide precursor of Example 1 is 20,000.

### Example 2

At room temperature, 14.94 g (0.071 mole) of 4,4′-diamino dicyclohexyl methane and 150 g (1.513 mole) of NMP are added into a reaction bottle with water bath. After the reactor is completely dissolved in NMP, 20.78 g (0.067 mole) of bis-(3-phthalyl anhydride)ether is added into the NMP solution, so as to being subjected to react.

After 16 hours, 17.44 g (0.134 mole) of 2-hydroxyethyl methacrylate is added, thereby performing the esterification reaction to an acidic group of the polyamic acid compound. After byproduct solid of dicyclohexylurea is filtered, polyimide precursor solution mixture is obtained. After water is added into the polyimide precursor solution mixture, precipitate is filtered and dried, thereby obtaining the polyimide precursor of Example 2. A molecular weight of the polyimide precursor of Example 2 is 19,000.

### Comparative Example 1

At room temperature, 14.94 g (0.071 mole) of 4,4′-diamino dicyclohexyl methane and 150 g (1.513 mole) of NMP are added into a reaction bottle with water bath. After the reactor is completely dissolved in NMP, 20.78 g (0.067 mole) of bis-(3-phthalyl anhydride)ether is added into the NMP solution, so as to being subjected to react.

After 16 hours, the polyimide precursor of Comparative Example 1 is obtained. A molecular weight of the polyimide precursor of Comparative Example 1 is 17,000.

### Producing Lithography Pattern

### Applied Example 1

30 parts by weight of the polyimide precursor of Example 1 and 1.5 parts by weight of photo-initiator are added in 68.5 parts by weight of solvent, so as to form a polyimide precursor solution. After the polyimide precursor solution is mixed uniformly, the solution (3 mL) is dropped on 4 inch Si-wafer substrate. A coating process is performed with 500 rpm (10 seconds) of initial rotary speed and 2000 rpm (20 seconds) of final rotary speed, thereby forming a coating film on the substrate.

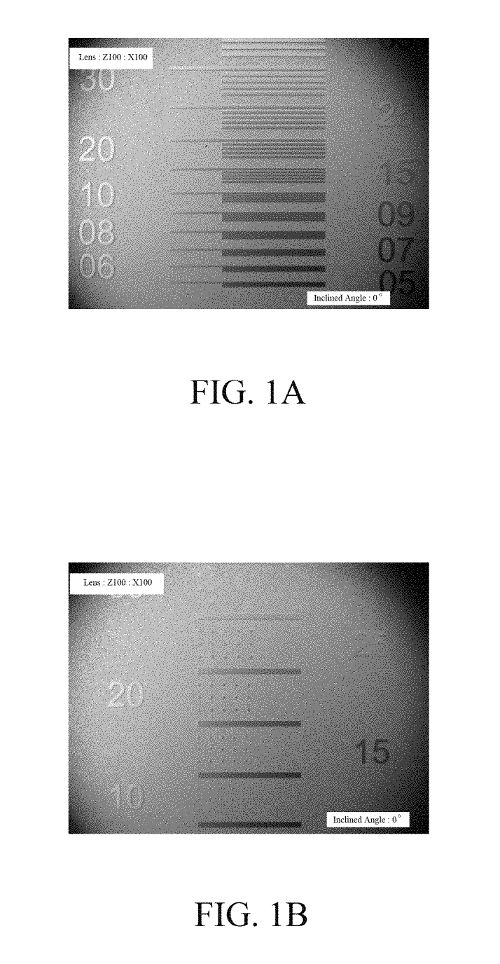

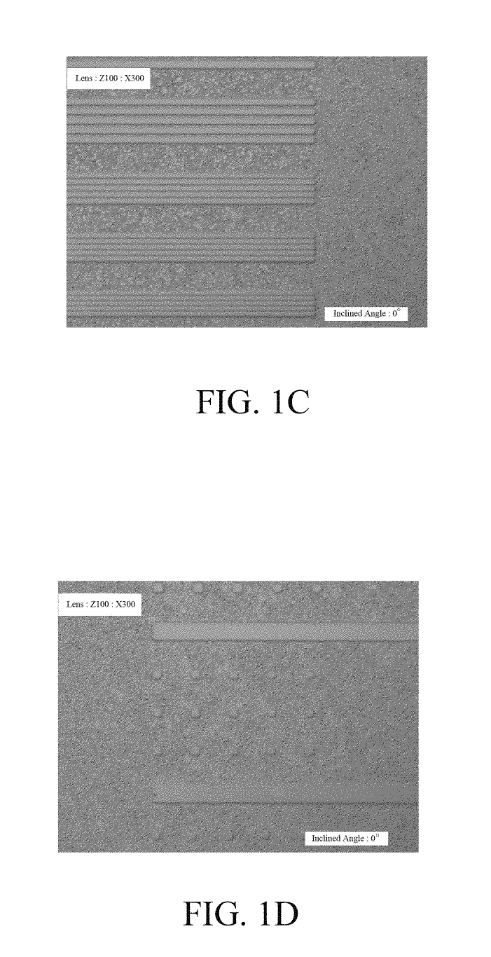

Then, the substrate with the coating film is subjected to the lithography process. In the lithography process, a development solution is cyclopentanone, and development period is 2 minutes; post-baking step is performed at 260° C. for 120 minutes. After the lithography process is performed, the lithography pattern of Applied Example 1 is obtained. The lithography pattern of Applied Example 1 is shown as FIG. 1A and FIG. 1B. FIG. 1A shows an optical microscope photograph of the lithography pattern formed according to Applied Example 1 of the present invention, and FIG. 1B shows another optical microscope photograph of the lithography pattern formed according to Applied Example 1 of the present invention.

### Applied Example 2 and Comparative Applied Example 1

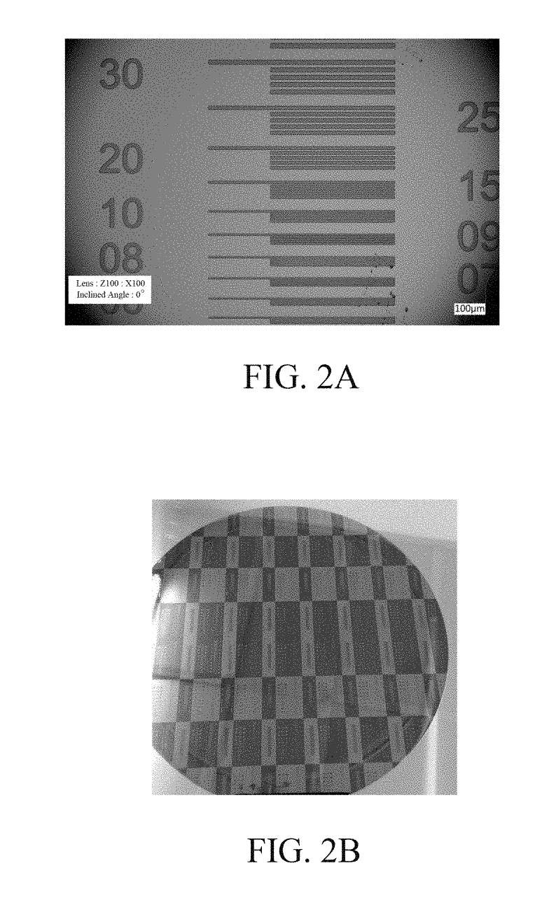

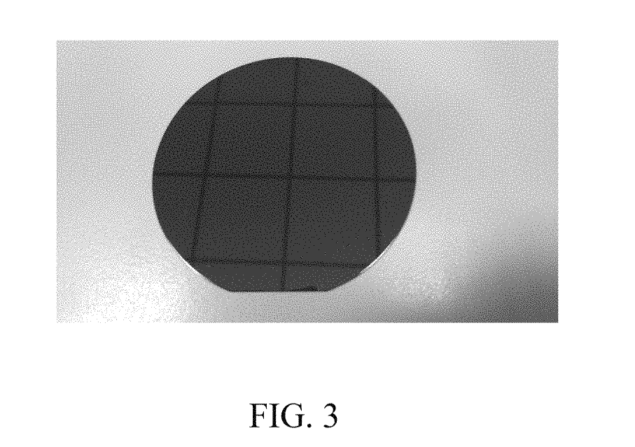

Applied Example 2 and Comparative Applied Example 1 are practiced with the same method as in Applied Example 1 by using various kinds of the polyimide precursor. The polyimide precursor of Example 2 is used in Applied Example 2, and the polyimide precursor of Comparative Example 1 is used in Comparative Applied Example 1. The lithography pattern of Applied Example 2 is shown as FIG. 2A and FIG. 2B, and the lithography pattern of Comparative Applied Example 1 is shown as FIG. 3. FIG. 2A shows an optical microscope photograph of the lithography pattern formed according to Applied Example 2 of the present invention, FIG. 2B shows a photograph of the substrate of Applied Example 2 after the lithography process is performed, and FIG. 3 shows a photograph of the substrate of Comparative Applied Example 1 after the lithography process is performed.

Referring to FIG. 1A and FIG. 2A. In FIG. 1A and FIG. 2A, numerals shown in the lithography pattern respectively represents linewidth (μm), and magnifying powers of FIG. 1A and FIG. 2A are both 100×.

Based on FIG. 1A and FIG. 2A with same magnified lens and magnifying power, the lines with linewidth of 8 μm and 9 μm (shown in FIG. 1A) can be clearly defined in the lithography pattern of Applied Example 1; the lines with linewidth of 9 μm (shown in FIG. 2A) can be clearly defined in the lithography pattern of Applied Example 2.

Moreover, referring to FIG. 1A together with FIG. 1C, and FIG. 1B together with FIG. 1D. In FIG. 1B, numerals shown in the lithography pattern respectively represents width (μm) of the dot patterns, and magnifying power of FIG. 1B is 100×. FIG. 1C shows an enlarged photograph of the lithography pattern with a linewidth of 8 μm, 9 μm, 10 μm and 15 μm of FIG. 1A. FIG. 1D shows an enlarged photograph of the dot pattern with a width of 20 μm of FIG. 1B. Magnifying powers of FIG. 1C and FIG. 1D are both 300×.

In FIG. 1C, the linewidths of the lithography pattern are 15 μm, 10 μm, 9 μm and 8 μm in the order from top to bottom of the picture. When the linewidth is 8 μm, the lines of the lithography pattern can be clearly defined, and the lines respectively have complete pattern boundary. Similarly, in FIG. 1D, the dot patterns with the width of 20 μm respectively have excellent pattern boundary.

As the aforementioned description, comparing to the lithography pattern of Applied Example 2, because the polyimide precursor of Applied Example 1 further comprises the end-capping groups (i.e. the thermal-crosslinking groups), high temperature applied by the post-baking step can not only subject the polyimide precursor to the imidization reaction but also subject one end-capping group of one molecular section to react with another end-capping group of another molecular section, thereby elongating the molecular section of the polyimide precursor, therefore further lowering the solubility of polyimide precursor in the development solution. Accordingly, the polyimide precursor of Example 1 has much better pattern-forming property.

Besides, referring to FIG. 2B together with FIG. 3, because the polyimide precursor of Comparative Example 1 is not be modified by the alcohol compound with R₂ group, the polyimide precursor of Comparative Example 1 has higher activation energy and cyclization temperature, thereby hardly being reacted to form polyimide. Accordingly, when the coating film of Comparative Example 1 is subjected to the post-baking step, the polyimide precursor is hardly to be reacted to form polyimide, or the formed polyimide has lower molecular weight. Thus, the coating film has higher solubility in the development solution of the lithography process. Therefore, there is no the lithography pattern on the substrate shown in FIG. 3.

As the aforementioned description, the polyimide precursors of Example 1 and Example 2 both comprise the modified groups of ester groups. Because the introduced ester-modified groups are beneficial for reducing the activation energy and the cyclization temperature of the imidization reaction, the ester-modified groups are beneficial to form polyimide. Thus, the polyimide has excellent pattern-forming property. Moreover, when the molecular section of the polyimide precursor comprises end-capping group (e.g. the polyimide precursor of Example 1), the polyimide precursor has much better pattern-forming property because the end-capping groups are beneficial to elongate the molecular sections.

Besides, the thermal-crosslinking groups, the photosensitive-crosslinking groups or the hydrogen atom (i.e. R₂ group in formula (I)) is introduced to the repeating unit shown as the formula (I), so as to increase the pattern-forming property of the polyimide precursor during an exposure step and post-baking step of the lithography process is performed. Moreover, when the polyimide precursor further comprises end-capping groups of the thermal-crosslinking groups, the polyimide precursor can have much better pattern-forming property. Furthermore, when the diamine compound of the present invention is the diamine compound having aliphatic groups, the polyimide precursor has excellent light transmission and solubility, such that the polyimide precursor can applied to produce polyimide protecting film, thereby enhancing convenience of application.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A polyimide precursor, having a repeating unit having a structure of following formula (I): 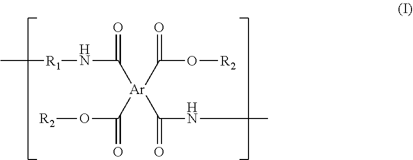
in the formula (I), Ar represents a tetravalent group derivated from a tetracarboxylic dianhydride compound; R₁ represents a divalent group derivated from a diamine compound; and R₂ independently represents a thermal-crosslinking group, a photosensitive-crosslinking group, or a hydrogen atom.

2. The polyimide precursor of claim 1, wherein Ar represents 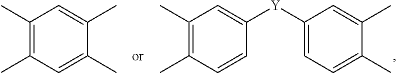
and Y represents a single bond, —O—, —CH₂—, —C(CH₃)₂—, —C(CF₃)₂—, —SO₂—, or —CO—.

3. The polyimide precursor of claim 1, wherein R₁ represents 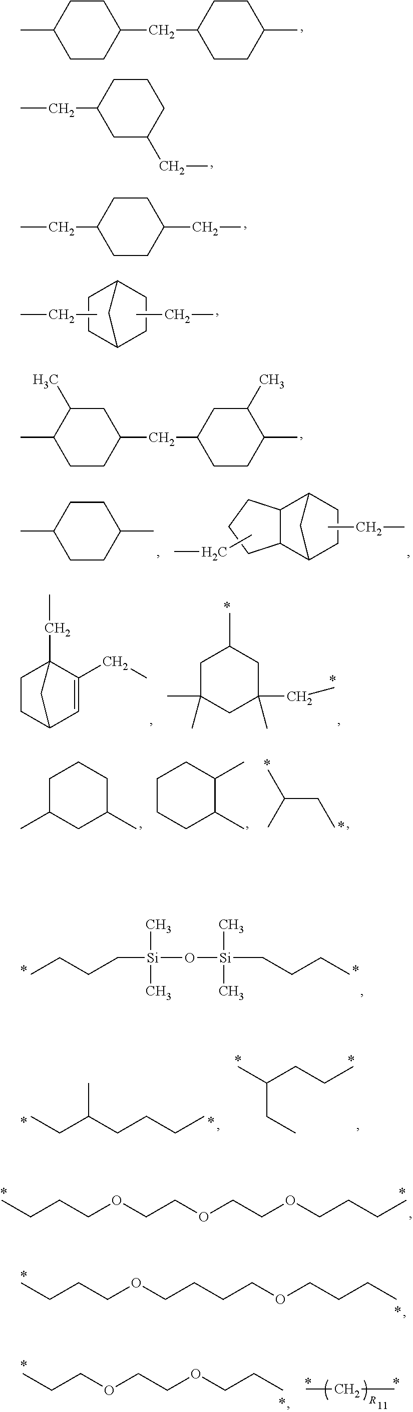
(R₁₁ represents an integer of 3 to 12), 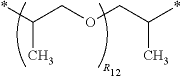
(R₁₂ represents a numeric value of 2 to 68), or 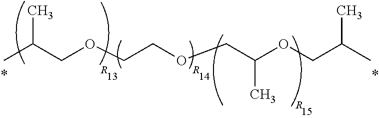
(R₁₄ represents a numeric value of 9 to 39, and a sum of R₁₃ and R₁₅ is a numeric value of 3 to 6).

4. The polyimide precursor of claim 1, wherein R₂ independently represents 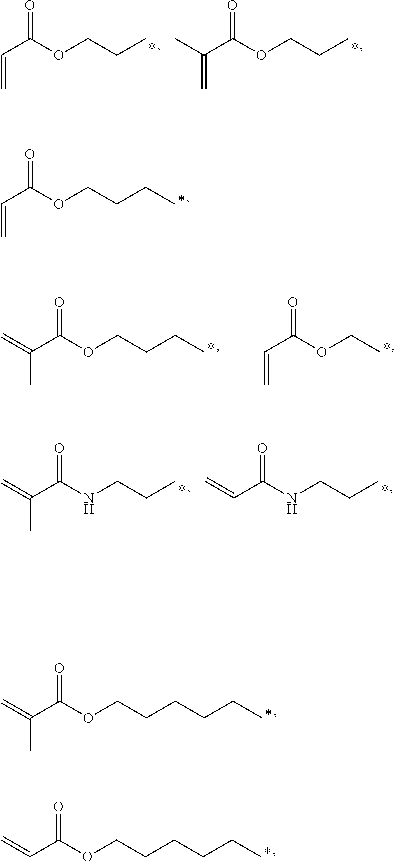 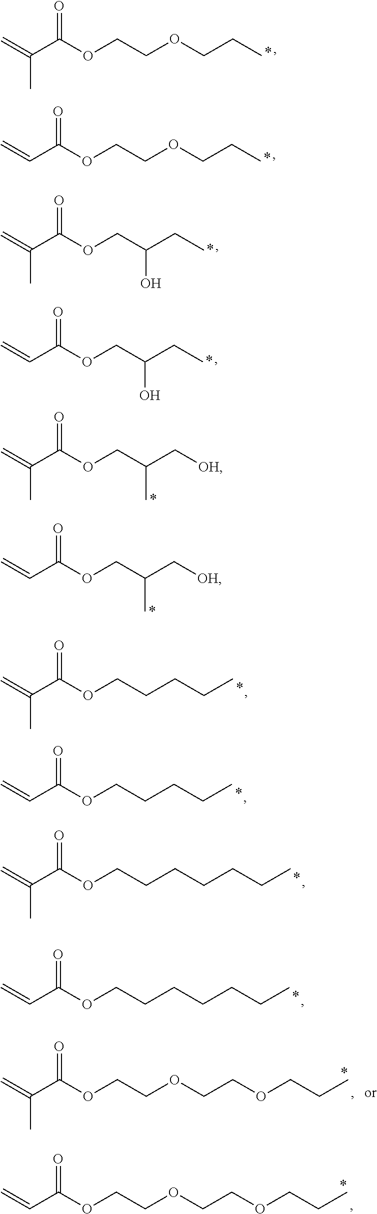
and “*” represents a position where R₂ is bonded with the oxygen atom of formula (I).

5. The polyimide precursor of claim 1, wherein a number of the repeating unit of the polyimide precursor is 2 to 150.

6. The polyimide precursor of claim 1, wherein two terminals of a molecular chain of the polyimide precursor include a first end-capping group and a second end-capping group, the first end-capping group is bonded with R₁ of the formula (I), and the second end-capping group is bonded with nitrogen atom of the formula (I).

7. The polyimide precursor of claim 6, wherein the first end-capping group and the second end-capping group respectively is a thermal-crosslinking group.

8. The polyimide precursor of claim 6, wherein the first end-capping group has a structure of —X; the second end-capping group has a structure of —R₁—X; X respectively represents 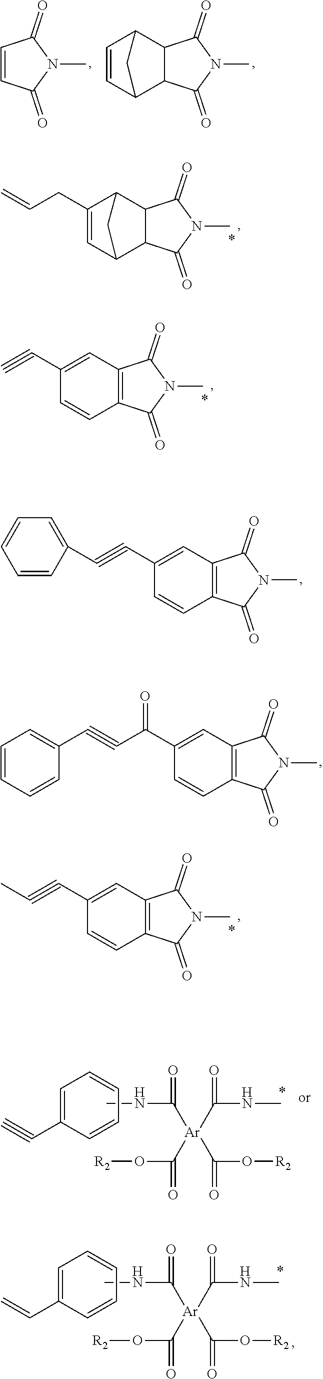
Ar represents a tetravalent group derivated from a tetracarboxylic dianhydride compound, R₂ independently represents the thermal-crosslinking group, the photosensitive-crosslinking group, or the hydrogen atom, and “*” represents a bonding position.

9. The polyimide precursor of claim 8, wherein Ar represents 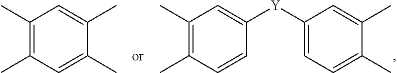
and Y represents a single bond, —O—, —CH₂—, —C(CH₃)₂—, —C(CF₃)₂—, —SO₂—, or —CO—; R₂ represents 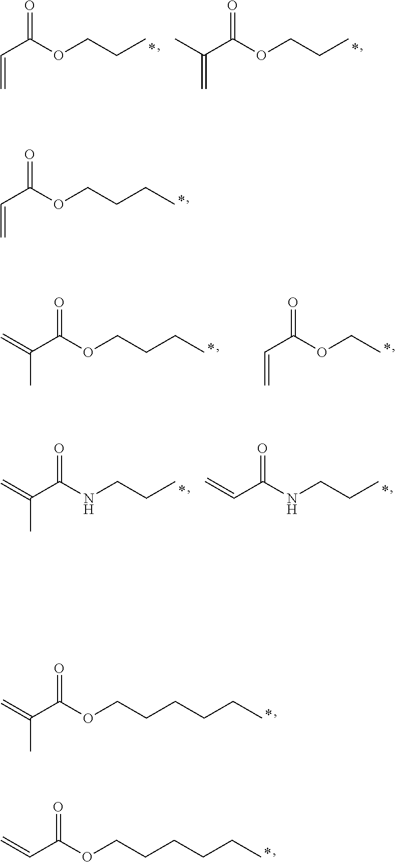 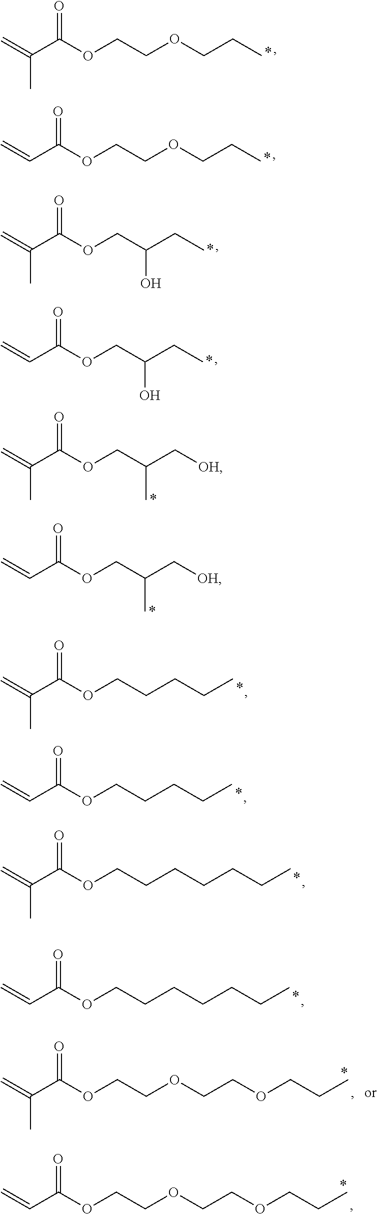
and “*” represents a position where R₂ is bonded with the oxygen atom.

10. A lithography pattern formed by performing a lithography process to a polyimide precursor, wherein the polyimide precursor has a repeating unit having a structure of following formula (I): 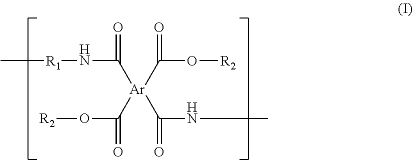
in the formula (I), Ar represents a tetravalent group derivated from a tetracarboxylic dianhydride compound; R₁ represents a divalent group derivated from a diamine compound; and R₂ independently represents a thermal-crosslinking group, a photosensitive-crosslinking group, or a hydrogen atom.

11. The lithography pattern of claim 10, wherein Ar represents 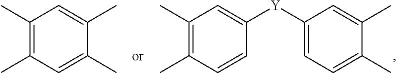
and Y represents a single bond, —O—, —CH₂—, —C(CH₃)₂—, —C(CF₃)₂—, —SO₂—, or —CO—.

12. The lithography pattern of claim 10, wherein R₁ represents 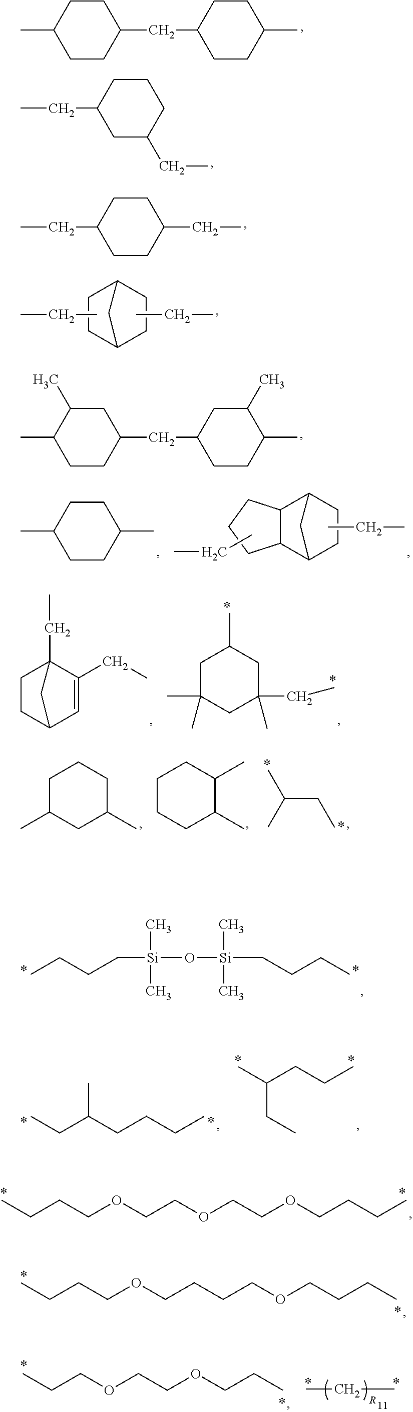
(R₁₁ represents an integer of 3 to 12), 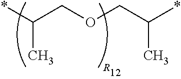
(R₁₂ represents a numeric value of 2 to 68), or 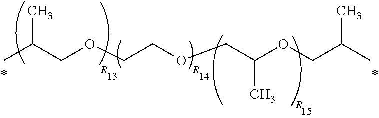
(R₁₄ represents a numeric value of 9 to 39, and a sum of R₁₃ and R₁₅ is a numeric value of 3 to 6).

13. The lithography pattern of claim 10, wherein R₂ independently represents 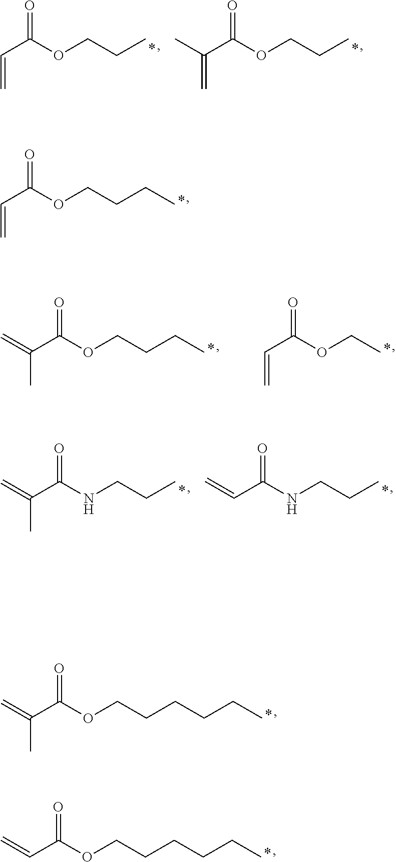 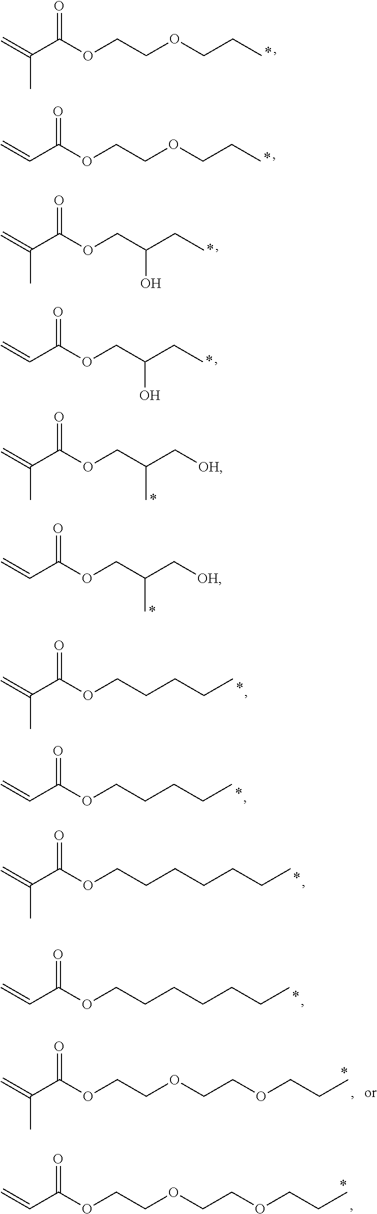
and “*” represents a position where R₂ is bonded with the oxygen atom of formula (I).

14. The lithography pattern of claim 10, wherein a number of the repeating unit of the polyimide precursor is 2 to 150.

15. The lithography pattern of claim 10, wherein two terminals of a molecular chain of the polyimide precursor include a first end-capping group and a second end-capping group, the first end-capping group is bonded with R₁ of the formula (I), and the second end-capping group is bonded with nitrogen atom of the formula (I).

16. The lithography pattern of claim 15, wherein the first end-capping group and the second end-capping group respectively a thermal-crosslinking group.

17. The lithography pattern of claim 15, wherein the first end-capping group has a structure of —X; the second end-capping group has a structure of —R₁—X; X respectively represents 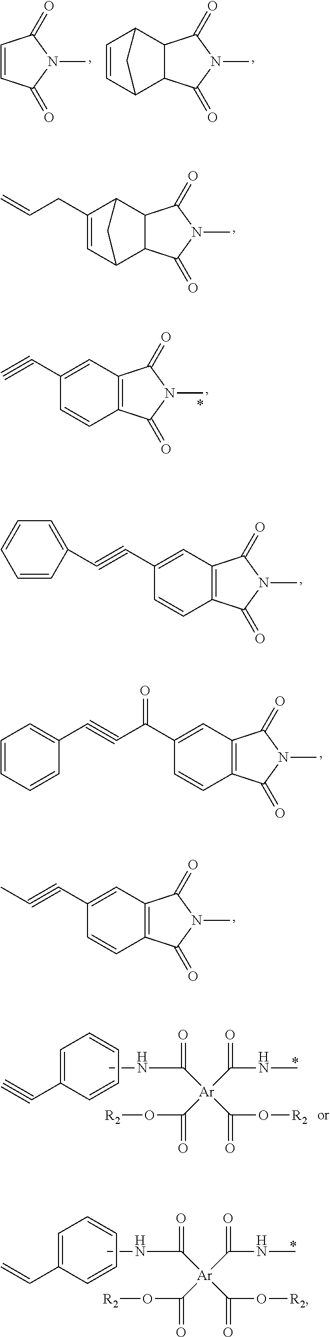
Ar represents a tetravalent group derivated from a tetracarboxylic dianhydride compound, R₂ independently represents the thermal-crosslinking group, the photosensitive-crosslinking group, or the hydrogen atom, and “*” represents a bonding position.

18. The lithography pattern of claim 17, wherein Ar represents 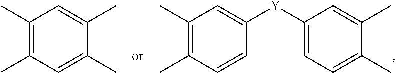
and Y represents a single bond, —O—, —CH₂—, —C(CH₃)₂—, —C(CF₃)₂—, —SO₂—, or —CO—; R₂ represents 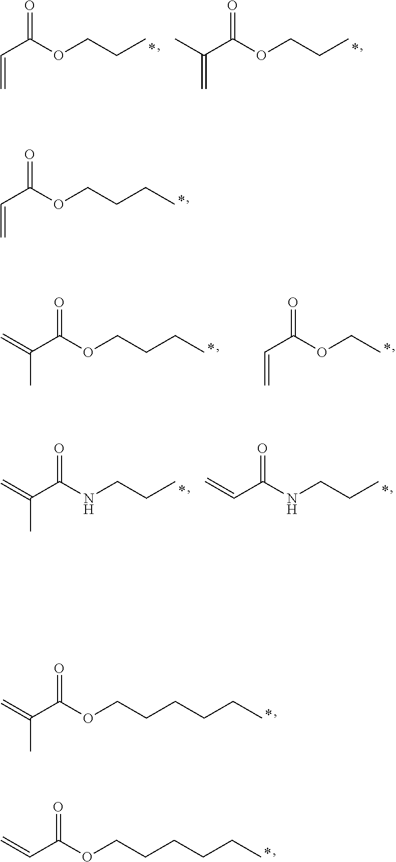 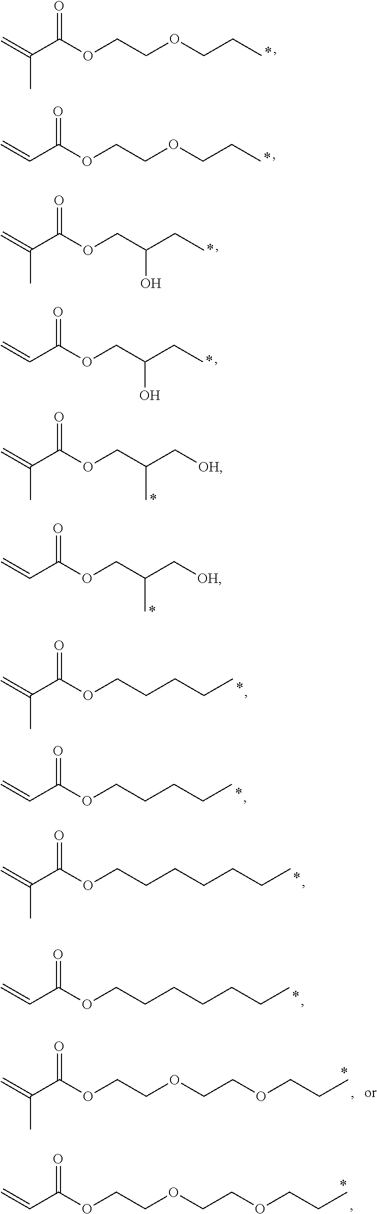
and “*” represents a position where R₂ is bonded with the oxygen atom.
